(19) United States
(12) Patent Application Publication
(10) Pub. No.: US 2025/0329603 A1
(43) Pub. Date: Oct. 23, 2025

(54) CTE MATCHED COINED LID FOR AIR-CAVITY PACKAGE TOP-SIDE COOLING

(71) Applicant: Qorvo US, Inc., Greensboro, NC (US)

(72) Inventors: MD Hasnine, Richardson, TX (US); Neftali Salazar, Murphy, TX (US)

(21) Appl. No.: 19/051,885

(22) Filed: Feb. 12, 2025

Related U.S. Application Data
(60) Provisional application No. 63/636,273, filed on Apr. 19, 2024.

(51) Int. Cl. H01L 23/367; H01L 21/50; H01L 23/00; H01L 23/10; H01L 23/31; H01L 25/07

(52) U.S. Cl. CPC H01L 23/3675; H01L 21/50; H01L 23/10; H01L 23/315; H01L 24/16; H01L 24/32; H01L 24/73; H01L 25/072; H01L 2224/16227; H01L 2224/32225; H01L 2224/73253

(57) ABSTRACT

The present disclosure relates to an air-cavity package including a base assembly with a package substrate and a flip-chip die attached to the package substrate, and a coined lid over the base assembly and including a lid body and a heat spreader. The lid body includes a lid base and a lid wall protruding from a periphery of the lid base towards the package substrate. The heat spreader extends through the lid base, protrudes from the lid base towards the package substrate, and is positioned over, aligned with, and thermally coupled to the flip-chip die. A lid sealing component seals the lid wall to the package substrate. Herein, a recess, which is defined underneath the lid base, surrounding the heat spreader, and surrounded by the lid wall, and a gap surrounding the flip-chip die combine to form a sealed air cavity. The flip-chip die is encapsulated within the air cavity.

### RELATED APPLICATIONS

This application claims the benefit of U.S. provisional patent application Ser. No. 63/636,273, filed on Apr. 19, 2024, the disclosure of which is hereby incorporated herein by reference in its entirety.

### FIELD OF THE DISCLOSURE

The present disclosure relates to an air-cavity package with a coined lid that provides an efficient path for top-side cooling and improves thermo-mechanical reliability.

### BACKGROUND

With faster switching speed, higher breakdown strength, and lower on-resistance, high-power radio frequency (RF) devices based on gallium nitride (GaN) technology significantly outperform silicon-based devices. To further enhance the breakdown voltage and maximum output power, gate spacing of GaN devices is desired to decrease. As the gate spacing of the GaN devices reduces, there is an increase in concentrated heat flux in active regions. Effectively managing device heating and controlling junction temperatures becomes essential, given their potential to negatively impact performance and reliability. In the case of the high-power RF devices attached to a package substrate, the ability to dissipate large amounts of heat through the package substrate underneath the devices (bottom-side cooling) is limited. This limitation results in high thermal resistance, ultimately degrading the device's lifetime. In addition, depending solely on heat sinks attached to the package substrate has been proven insufficient for dissipating highly concentrated heat flux.

On the other hand, air-cavity packages are widely used for the high-power RF applications. Dry air within the packages provides a considerably lower dielectric constant than typical mold compounds, thus reducing losses and providing improved electrical performance at high frequencies.

Accordingly, there remains a need for improved packaging designs, which utilize the air-cavity configuration for reduced losses and enhanced electrical performance, and provide an efficient path for heat dissipation of the high-power devices.

### SUMMARY

The present disclosure relates to an air-cavity package with a coined lid that provides an efficient path for top-side cooling and improves thermo-mechanical reliability. The disclosed air-cavity package includes a base assembly, a coined lid placed over the base assembly, and a lid sealing component coupled between the base assembly and the coined lid. Herein, the base assembly includes a package substrate and at least one flip-chip die attached to a top surface of the package substrate, and the coined lid includes a lid body and at least one heat spreader. The lid body includes a lid base and a lid wall protruding from a periphery of a bottom surface of the lid base towards the top surface of the package substrate. The at least one heat spreader extends through the lid base and protrudes from the bottom surface of the lid base. A recess is defined underneath the lid base, surrounding the at least one heat spreader, and surrounded by the lid wall. The at least one heat spreader is positioned over, aligned with, and thermally coupled to the at least one flip-chip die. The lid sealing component seals the lid wall to the top surface of the package substrate, such that the recess within the coined lid and a gap surrounding the at least one flip-chip die combine to form an air cavity, which is sealed by a combination of the coined lid, the package substrate, and the lid sealed component. The at least one flip-chip die is encapsulated within the air cavity.

In one embodiment of the air-cavity package, the at least one heat spreader is formed from an engineered nano copper paste, which is capable of being customized in a coefficient of thermal expansion (CTE), in a range of 5-16 ppm.

In one embodiment of the air-cavity package, the at least one flip-chip die includes a die body and a number of interconnects extending outwardly from a bottom surface of the die body and is coupled to the top surface of the package substrate.

In one embodiment of the air-cavity package, the die body is formed from gallium nitride (GaN).

In one embodiment of the air-cavity package, the at least one heat spreader is thermally coupled to a backside of the die body via a sintered component.

In one embodiment of the air-cavity package, both the at least one heat spreader and the sintered component are formed from an engineered nano copper paste, which is capable of being customized in the CTE, in a range of 5-16 ppm.

In one embodiment of the air-cavity package, the at least one heat spreader is rectangular, square, round, T-shaped, or octagonal.

In one embodiment of the air-cavity package, the lid body further includes at least one lid ridge, which is located in an inner area of the lid body and protrudes from the bottom surface of the lid base towards the top surface of the package substrate. The at least one heat spreader extends through the lid base and the at least one lid ridge, such that a top surface and a bottom surface of the at least one heat spreader are not covered by any portion of the lid body, while side surfaces of the at least one heat spreader are covered by the lid body.

In one embodiment of the air-cavity package, a portion of the at least one heat spreader is not covered by the lid body and is exposed to the recess.

In one embodiment of the air-cavity package, the lid body is formed from a flame-retardant glass reinforced epoxy laminate material (FR4) or liquid crystal polymer (LCP).

According to one embodiment, the air-cavity package further includes a heat sink, which is coupled to a top surface of the coined lid via an adhesion layer.

In one embodiment of the air-cavity package, the lid sealing component is formed from an epoxy material.

According to one embodiment, a method of fabricating an air-cavity package starts with forming a base assembly and forming a coined lid. The base assembly includes a package substrate and at least one flip-chip die attached to a top surface of the package substrate, while the coined lid includes a lid body and at least one heat spreader. Herein, the lid body includes a lid base and a lid wall protruding from a periphery of a bottom surface of the lid base towards the top surface of the package substrate. The at least one heat spreader extends through the lid base and protrudes from the bottom surface of the lid base. A recess is defined underneath the lid base, surrounding the at least one heat spreader, and surrounded by the lid wall. Next, the coined lid is placed over the base assembly, such that the at least one heat spreader is positioned over, aligned with, and thermally coupled to the at least one flip-chip die. The lid wall of the coined lid is then sealed to the top surface of the package substrate by a lid sealing component. The recess within the coined lid and a gap surrounding the at least one flip-chip die combine to form an air cavity, which is sealed by a combination of the coined lid, the package substrate, and the lid sealed component. The at least one flip-chip die is encapsulated within the air cavity.

In one embodiment of the method, the at least one heat spreader is formed from an engineered nano copper paste, which is capable of being customized in CTE, in a range of 5-16 ppm.

According to one embodiment, the method further includes applying a sintering material to a backside of the at least one flip-chip die after the base assembly is formed. As such, when the coined lid is placed over the base assembly, the at least one heat spreader is coupled to the at least one flip-chip die via the sintering material.

In one embodiment of the method, the sintering material is the engineered nano copper paste, which is capable of being customized in the CTE, in a range of 5-16 ppm.

According to one embodiment, the method further includes applying a lid sealing material on a top surface of the package substrate after the base assembly is formed. Herein, a position of the lid sealing material on the top surface of the package substrate corresponds to a position of the lid wall on the lid base, such that when the coined lid is placed over the base assembly, the lid sealing material is coupled between the top surface of the package substrate and the bottom surface of the lid wall.

In one embodiment of the method, the lid sealing material is an epoxy material.

In one embodiment of the method, sealing the lid wall of the coined lid to the top surface of the package substrate includes at least one curing process, which converts the lid sealing material to the lid sealing component that connects the bottom surface of the lid wall to the top surface of the package substrate, and converts the sintering material to a sintered component that connects a bottom surface of the at least one heat spreader to the backside of the at least one flip-chip die.

According to one embodiment, a communication device includes a control system, a baseband processor, receive circuitry, and transmit circuitry. Herein, at least one or any combination of the control system, the baseband processer, the transmit circuitry, and the receive circuitry may be implemented in an air-cavity package. The air-cavity package includes a base assembly, a coined lid placed over the base assembly, and a lid sealing component coupled between the base assembly and the coined lid. Herein, the base assembly includes a package substrate and at least one flip-chip die attached to a top surface of the package substrate, and the coined lid includes a lid body and at least one heat spreader. The lid body includes a lid base and a lid wall protruding from a periphery of a bottom surface of the lid base towards the top surface of the package substrate. The at least one heat spreader extends through the lid base and protrudes from the bottom surface of the lid base. A recess is defined underneath the lid base, surrounding the at least one heat spreader, and surrounded by the lid wall. The at least one heat spreader is positioned over, aligned with, and thermally coupled to the at least one flip-chip die. The lid sealing component seals the lid wall to the top surface of the package substrate, such that the recess within the coined lid and a gap surrounding the at least one flip-chip die combine to form an air cavity, which is sealed by a combination of the coined lid, the package substrate, and the lid sealed component. The at least one flip-chip die is encapsulated within the air cavity.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary air-cavity package according to some embodiments of the present disclosure.

FIGS. 2-4 illustrate an alternative configuration of the air-cavity package according to some embodiments of the present disclosure.

FIGS. 5A-5C illustrate flowcharts of a process of fabricating the air-cavity package according to some embodiments of the present disclosure.

FIGS. 6-18 illustrate steps associated with the fabricating process provided in FIGS. 5A-5C.

FIG. 19 is a block diagram of a communication device, which may include the air-cavity package illustrated in FIGS. 1-4 according to some embodiments of the present disclosure.

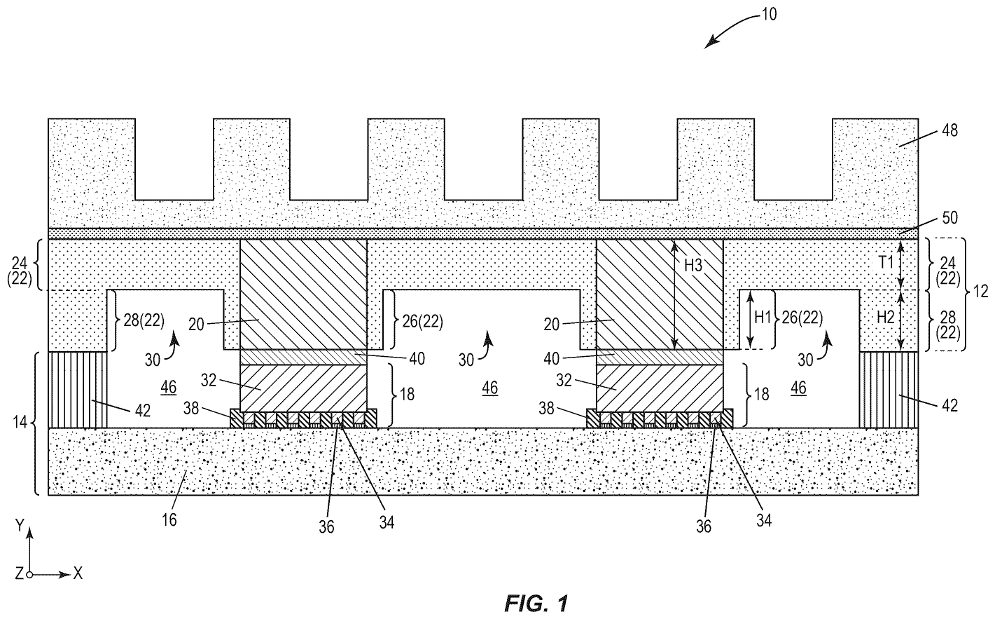

It will be understood that for clear illustrations, FIGS. 1-19 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

For high-power radio frequency (RF) devices, such as gallium nitride (GaN) devices, bottom-side cooling through a package laminate substrate is limited, which may negatively impact electrical performance and device reliability. Top-side cooling for the high-power RF devices is imperative to establish as an alternative or an additional thermal pathway to an ambient environment. Compared to wire-bonding dies, flip-chip assembly technology, besides its preferable solder interconnection to the package substrate (which helps in reducing the die size, reducing the overall size of the package, shorting the electrical path to the package laminate substrate, and reducing undesired inductance and capacitance), also provides the capability for the top-side cooling. A backside (i.e., the tallest portion) of one flip chip die is typically inactive, which allows the backside of the flip chip die to be connected to a high thermally conductive component above, so as to provide an upward heat dissipation path.

FIG. 1 illustrates an exemplary air-cavity package 10 with a coined lid 12, which provides an efficient path for top-side cooling and improves thermo-mechanical reliability, according to some embodiments of the present disclosure. Besides the coined lid 12, the air-cavity package 10 also includes a base assembly 14 with a package substrate 16, and one or more electrical components 18 attached to a top surface of the package substrate 16. The coined lid 12 is placed over the base assembly 14 and is configured to provide a top cooling path for the electrical components 18.

For the purpose of this illustration, the coined lid 12 includes two heat spreaders 20 and a lid body 22 with a lid base 24, two lid ridges 26, and a lid wall 28. Herein, each lid ridge 26 is located in an inner area of the lid body 22 and protrudes from a bottom surface of the lid base 24 towards the top surface of the package substrate 16. The lid wall 28 is located in a peripheral area of the lid body 22 and protrudes from a periphery of the bottom surface of the lid base 24 towards the top surface of the package substrate 16. Each heat spreader 20 may have a rectangular shape in x-y dimensions and extends through the lid base 24 and a corresponding lid ridge 26, such that only a top surface and a bottom surface of each heat spreader 20 are not covered by any portion of the lid body 22 (e.g., the top surface of each heat spreader 20 is flashed with a top surface of the lid base 24, and the bottom surface of each heat spreader 20 is flashed with a bottom surface of the corresponding lid ridge 26), while side surfaces of each heat spreader 20 are covered by the lid body 22. The lid wall 28 and the lid ridges 26 extend vertically beyond the bottom surface of the lid base 24 to define a recess 30 underneath the lid base 24 and among the lid wall 28 and the lid ridges 26 (e.g., the recess 30 is continuous and surrounds each lid ridge 26). In different applications, the coined lid 12 may include fewer or more heat spreaders 20 and corresponding fewer or more lid ridges 26. Each heat spreader 20 may have a different shape in the x-y dimensions, such as square, round, T-shape, octagonal, or any other appropriate shape.

Each heat spreader 20 may be formed from a nano copper paste, which is capable of being customized in a coefficient of thermal expansion (CTE), in the range of 5-16 ppm (more details are described in the following descriptions). The lid body 22 may be formed from an insulated polymeric material, such as a flame-retardant glass reinforced epoxy laminate material (FR4), liquid crystal polymer (LCP), or the like. The lid base 24 has a thickness T1 between 0.5 mm and 3.0 mm, each lid ridge 26 has a height H1 between 0.5 mm and 1.0 mm, the lid wall 28 has a height H2 between 0.5 mm and 2.0 mm, and each heat spreader 20 has a height H3 between 1.0 mm and 4.0 mm.

In this illustration, the one or more electrical components 18 are two flip-chip dies 18, each of which includes a die body 32 and multiple interconnects 34 extending outwardly from a bottom surface of the die body 32 and is coupled to the top surface of the package substrate 16. The die body 32 may be formed from GaN, and the interconnects 34 may be copper pillars that are coupled to the package substrate 16 via solder caps 36, respectively (only one interconnect and one solder cap of one flip-chip die 18 are labeled with reference numbers for clarity). Each flip-chip die 18 may be underfilled by an underfilling material 38, such as an epoxy material, which encapsulates each interconnect 34 and fills gaps between the bottom surface of the die body 32 and the top surface of the package substrate 16. The package substrate 16 may typically be formed from organic materials and copper (used as internal connections within the organic material), a combination of which has a relatively low thermal conductivity. The package substrate 16 may have a thickness between 200 μm and 600 μm. In different applications, the base assembly 14 may include fewer or more flip-chip dies 18, and may also include resistors, capacitors, inductors, wire-bonding dies, and/or other surface mounted devices (SMDs) attached to the top surface of the package substrate 16.

In one embodiment, the number of the heat spreaders 20 may depend on a number of the flip-chip dies 18 included in the base assembly 14. The bottom surface of each heat spreader 20 is vertically aligned with and thermally coupled to a backside of a corresponding flip-chip die 18 via one sintered component 40. Each heat spreader 20 may have a size and shape that substantially matches the backside of the corresponding flip-chip die 18 in x-z dimensions (e.g., a rectangular/square shape, not shown). Herein, substantially matching in a size and shape refers to matching at least 80%-90% in size and shape. Each lid ridge 26 may provide extra mechanical support to the corresponding flip-chip die 18. If the flip-chip dies 18 have different heights, the sintered components 40 may have different thicknesses, respectively, so as to connect each heat spreader 20 to its corresponding flip-chip die 18 (e.g., one shorter flip-chip die 18 corresponds to a thicker sintered component 40). Each sintered component 40 may be formed from the nano copper paste (e.g., same as the heat spreaders 20), such that each combination of one sintered component 40 and its corresponding heat spreader 20 can help to mitigate CTE mismatches between the lid body 22, the flip-chip dies 18, and the package substrate 16. In some cases, the sintered component 40 may be formed from sintering silver, where each heat spreader 20 still can help to mitigate CTE mismatches between the lid body 22, the flip-chip dies 18, and the package substrate 16.

Herein, heat generated by each flip-chip die 18 (e.g. from an active region of the die body 32 adjacent to the interconnects 34) is capable of being efficiently dissipated upward (i.e., top-side cooling) to the ambient environment through a corresponding combination of the sintered component 40 and the heat spreader 20. The heat generated by each flip-chip die 18 may also be dissipated downward (i.e., bottom-side cooling), although limitedly, to the ambient environment through the corresponding interconnects 34 and the package substrate 16.

In addition, the air-cavity package 10 further includes a lid sealing component 42 that seals the lid wall 28 to the top surface of the package substrate 16. The recess 30 within the coined lid 12 and a continuous gap surrounding each flip-chip die 18 combine to form an air cavity 46 within the air-cavity package 10, which is sealed by a combination of the coined lid 12, the package substrate 16, and the lid sealed component 42. Each flip-chip die 18 is encapsulated within the sealed air cavity 46 by the combination of the coined lid 12, the package substrate 16, and the lid sealed component 42. Herein, since each flip-chip die 18 is exposed in the sealed air cavity 46, which provides a considerably lower dielectric constant than typical encapsulation mold compounds, improved electrical performance of the flip-chip dies 18 at high frequencies can be achieved. To further enhance the top cooling of the air-cavity package 10, the air-cavity package 10 may also include a heat sink 48 coupled to a top surface of the coined lid 12 via an adhesion layer 50. As such, the heat generated from the flip-chip dies 18 can be dissipated through the combination of the sintered components 40 and the heat spreaders 20, and towards the heat sink 48.

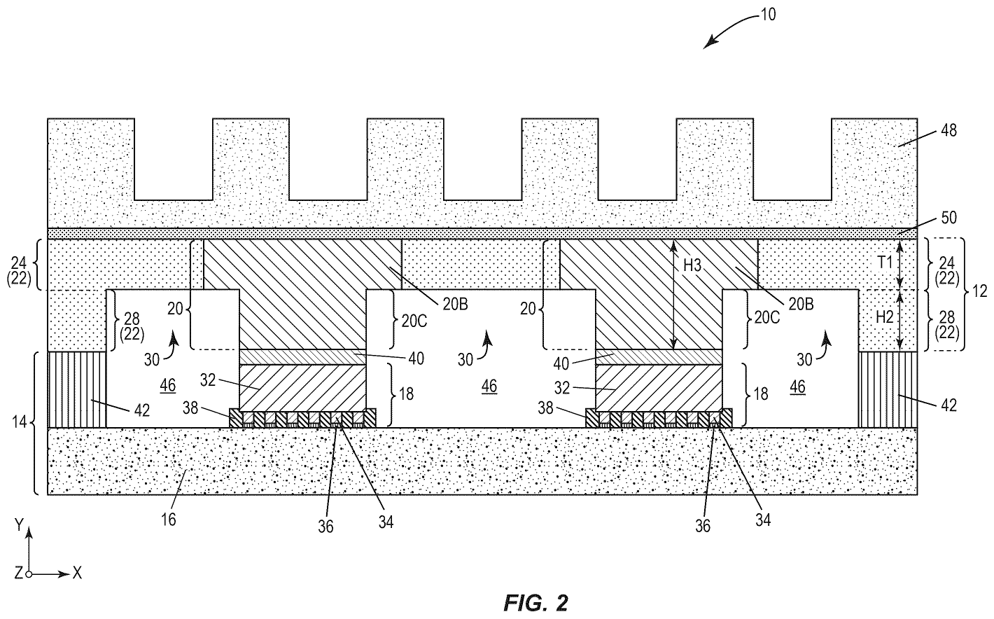

In some applications, if the size of the flip chip die 18 is small, the heat spreaders 20 may be modified to a T-shape to enhance heat spreading capability, as shown in FIG. 2. For the purpose of this illustration, the coined lid 12 still includes two heat spreaders 20 and the lid body 22. However, the lid body 22 only includes the lid base 24 and the lid wall 28 protruding from the periphery of the bottom surface of the lid base 24, while the interior lid ridges 26 are omitted in the lid body 22. Herein, each heat spreader 20 may include a spreader base 20B and a spreader column 20C that protrudes from a bottom surface of the spreader base 20B toward the top surface of the package substrate 16. In the x-z dimensions, a size of each spreader column 20C substantially matches the size and shape of the corresponding flip-chip die 18, while the size of each spreader base 20B is larger than a corresponding spreader column 20C (so as to form a T-shape). Each spreader base 20B extends through the lid base 24 (e.g., a top surface of each spreader base 20B is flashed with the top surface of the lid base 24, and the bottom surface of each spreader base 20B is flashed with the bottom surface of the lid base 24), while each spreader column 20C extends beyond the lid base 24 and is not covered by any portion of the lid body 22. The recess 30 is defined underneath the lid base 24 and among the lid wall 28 and the spreader columns 20C (e.g., the recess 30 is continuous and directly surrounds the spreader column 20C of each heat spreader 20). The bottom surface of each heat spreader 20 (i.e., a bottom surface of each spreader column 20C) and a bottom surface of the lid wall 28 may be on a same plane.

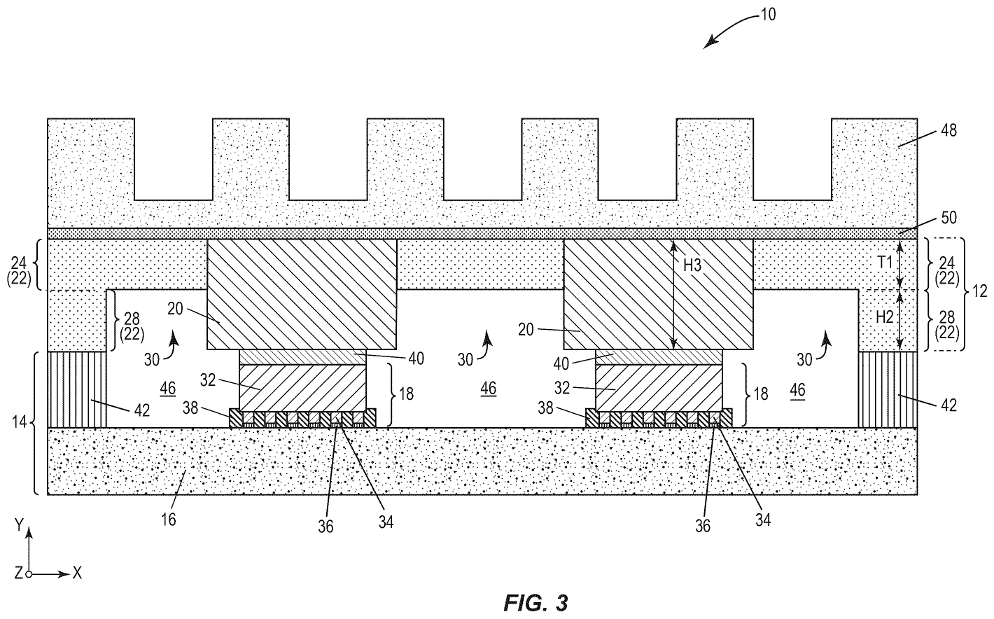

In some applications, the x-z dimensions of one heat spreader 20 that substantially matches the corresponding flip-chip die 18 may not effectively reduce the temperature of the die body 32 (especially the active region of the die body 32 adjacent to the interconnects 34). To further enhance the upward heat dissipation (i.e., the top cooling), each heat spreader 20 may have a larger size in the x-z dimensions than the backside of the corresponding flip-chip die 18, as illustrated in FIG. 3. In the x-z dimensions, the size of each heat spreader 20 may be 1.5 times or even 2-3 times of the size of the corresponding flip-chip die 18 (not drawn to scale). For the purpose of this illustration, the coined lid 12 includes two heat spreaders 20 and the lid body 22 without the interior lid ridges 26. Each heat spreader 20 may have a rectangular shape in the x-y dimensions and extends through the lid base 24 and protrudes from the bottom surface of the lid base 24 toward the top surface of the package substrate 16. As such, the top surface of each heat spreader 20 is not covered by any portion of the lid body 22 (e.g., the top surface of each heat spreader 20 is flashed with a top surface of the lid base 24). Herein, a lower portion of each heat spreader 20 is not covered by any portion of the lid body 22. The recess 30 is defined underneath the lid base 24 and among the lid wall 28 and the heat spreaders 20 (e.g., the recess 30 is continuous and directly surrounds each heat spreader 20). The bottom surface of each heat spreader 20 and the bottom surface of the lid wall 28 may be on the same plane.

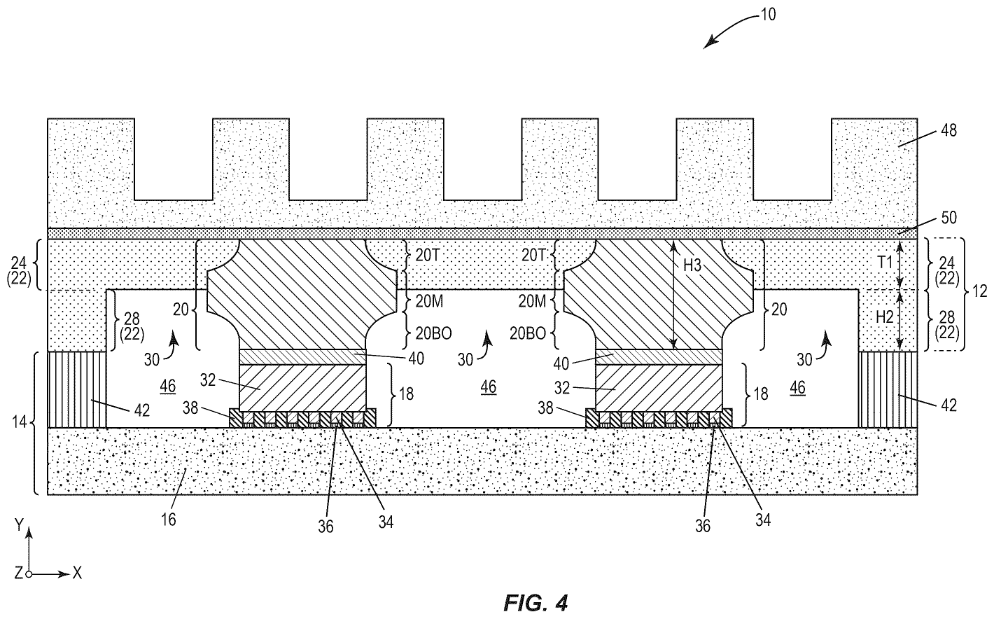

FIG. 4 illustrates that each heat spreader 20 may be modified as an octagonal shape to improve heat spreading capability. Herein, the coined lid 12 includes two heat spreaders 20 and the lid body 22 without the interior lid ridges 26. Each heat spreader 20 may have an octagonal shape in the x-y dimensions and can be divided into a top portion 20T, a middle portion 20M, and a bottom portion 20BO. A size of each top portion 20T and a size of each bottom portion 20BO are smaller than a size of a corresponding middle portion 20M. For the purpose of this illustration, the top portion 20T of each heat spreader 20 extends through the lid base 24, where a top surface of the top portion 20T (i.e., the top surface of each heat spreader 20) is not covered by any portion of the lid body 22 (e.g., the top surface of each heat spreader 20 is flashed with a top surface of the lid base 24). The middle portion 20M and the bottom portion 20BO of each heat spreader 20 protrude from the bottom surface of the lid base 24 toward the top surface of the package substrate 16, and are not covered by the lid body 22. The size of the bottom portion 20BO substantially matches the size of the corresponding flip-chip die 18 in the x-z dimensions. In different applications, the lid base 24 may cover more or less of each heat spreader 20, and the size of the bottom portion 20BO may be larger than the size of the corresponding flip-chip die 18 in the x-z dimensions. The recess 30 is defined underneath the lid base 24 and among the lid wall 28 and the heat spreaders 20 (e.g., the recess 30 is continuous and directly surrounds each heat spreader 20). The bottom surface of each heat spreader 20 and the bottom surface of the lid wall 28 may be on the same plane.

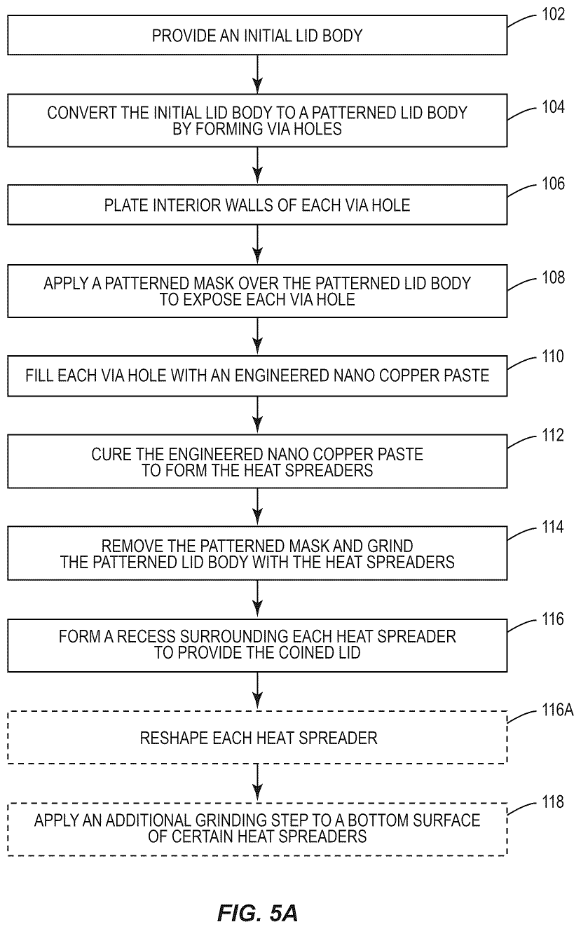

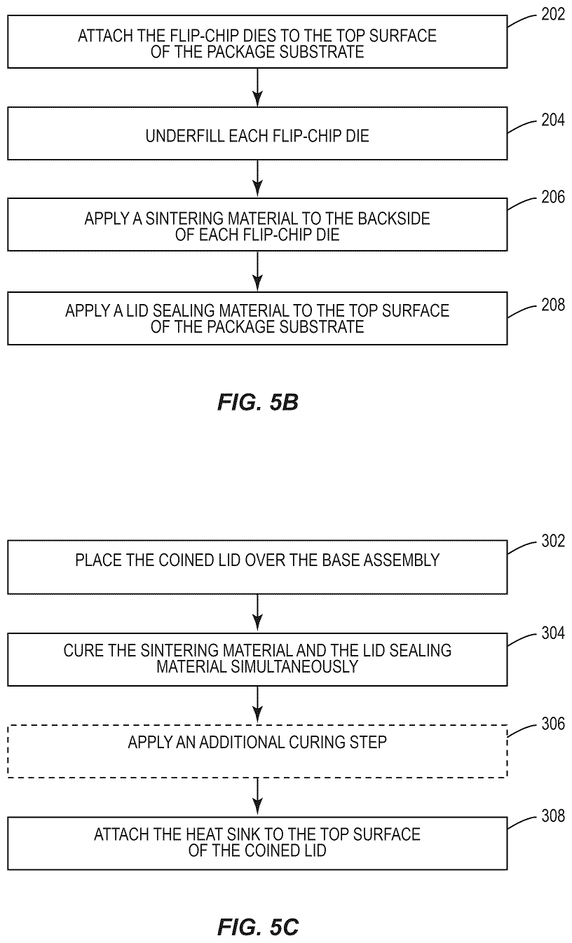

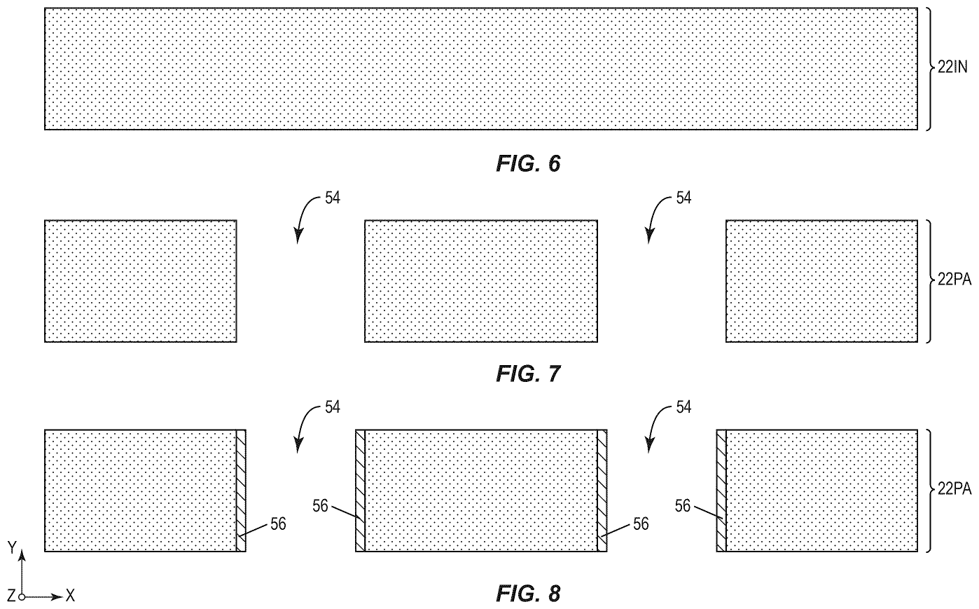

FIGS. 5A-5C provide flowcharts of a process of fabricating the air-cavity package 10 according to some embodiments of the present disclosure. In particular, FIG. 5A provides a process of forming the coined lid 12, FIG. 5B provides a process of forming the base assembly 14, and FIG. 5C provides a process of combining the coined lid 12 and the base assembly 14 to complete the air-cavity package 10. FIGS. 6-19 illustrate the steps associated with the fabricating process provided in FIGS. 5A-5C. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 6-19.

Initially, an initial lid body 22IN is provided (step 102) as illustrated in FIG. 6. The initial lid body 22IN may have a thickness T2 between 1.0 mm and 4.0 mm, and may be formed from an insulated polymeric material, such as FR4, liquid crystal polymer LCP, or the like. Next, a patterned lid body 22PA is converted from the initial lid body 22IN by forming one or more via holes 54 in the initial lid body 22IN (step 104), as illustrated in FIG. 7. Herein, the one or more via holes 54 are formed based on the sizes and relative locations of the flip-chip dies 18 that are intended to be thermally conducted. For the purpose of this illustration, two via holes 54 are formed vertically through the patterned lid body 22PA, each of which has a rectangular shape in the x-y dimensions. In different applications, there might be fewer or more via holes 54 formed through the patterned lid body 22PA, and the via holes 54 may have a different appropriate shape, such as round, square, octagonal, etc. The via holes 54 may be formed by a drilling process and/or a punching process. Interior walls of each via hole 54 are then fully plated with a plating material 56 (step 106) as illustrated in FIG. 8. The plating material 56 may be copper or gold and applied by an electroplating process.

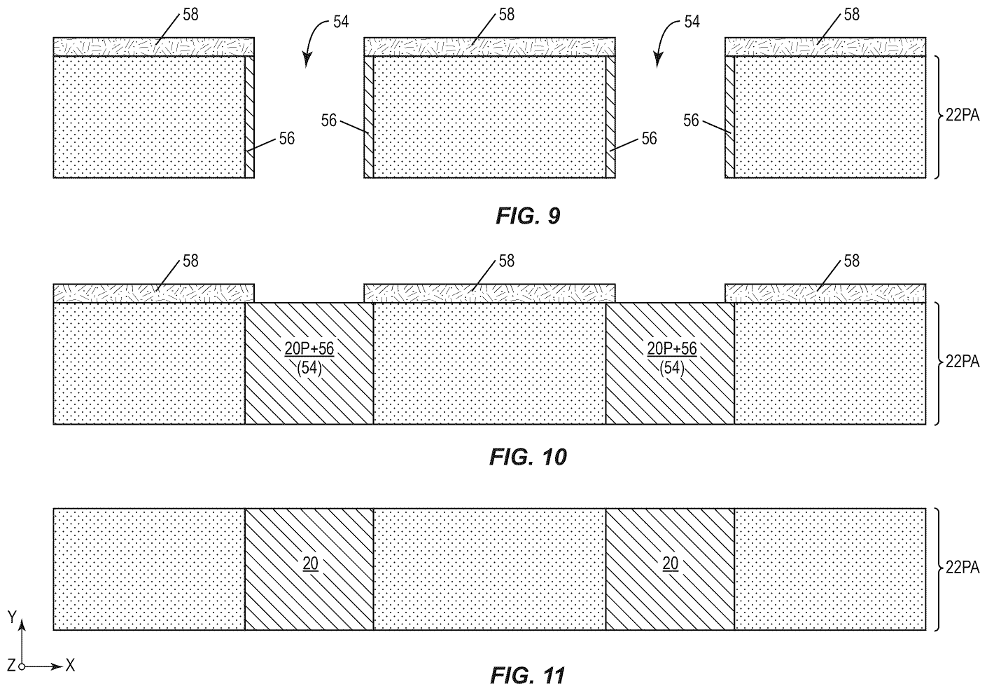

After the interior walls of each via hole 54 are plated, a patterned mask 58 is applied over the patterned lid body 22PA (step 108), which covers a top surface of the patterned lid body 22PA but exposes each via hole 54, as illustrated in FIG. 9. The pattern mask 58 is configured to ensure that the heat spreaders 20 are properly formed inside the via holes 54 in the following steps. Next, an engineered nano copper paste 20P is utilized to fill each via hole 54 (step 110) as illustrated in FIG. 10. Herein, this nano copper paste 20P is capable of being customized to closely match the CTE with corresponding flip-chip dies 18 (more details in the following description). Once the via holes 54 are filled with the nano copper paste 20P, a curing process (step 112, not shown), which involves pressing, clamping, and curing, is followed to convert the nano copper paste 20P combined with the plating material 56 into the cured heat spreaders 20. Subsequently, the patterned mask 58 is removed and the patterned lid body 22PA with the heat spreaders 20 are ground (step 114), as illustrated in FIG. 11. A top surface of the patterned lid body 22PA and the top surface of each heat spreader 20 may be in a same plane, while a bottom surface of the patterned lid body 22PA and the bottom surface of each heat spreader 20 may be in a same plane. Optionally, an extra plating step may be applied to the top surface and the bottom surface of each heat spreader 20 using a gold/nickel material (not shown).

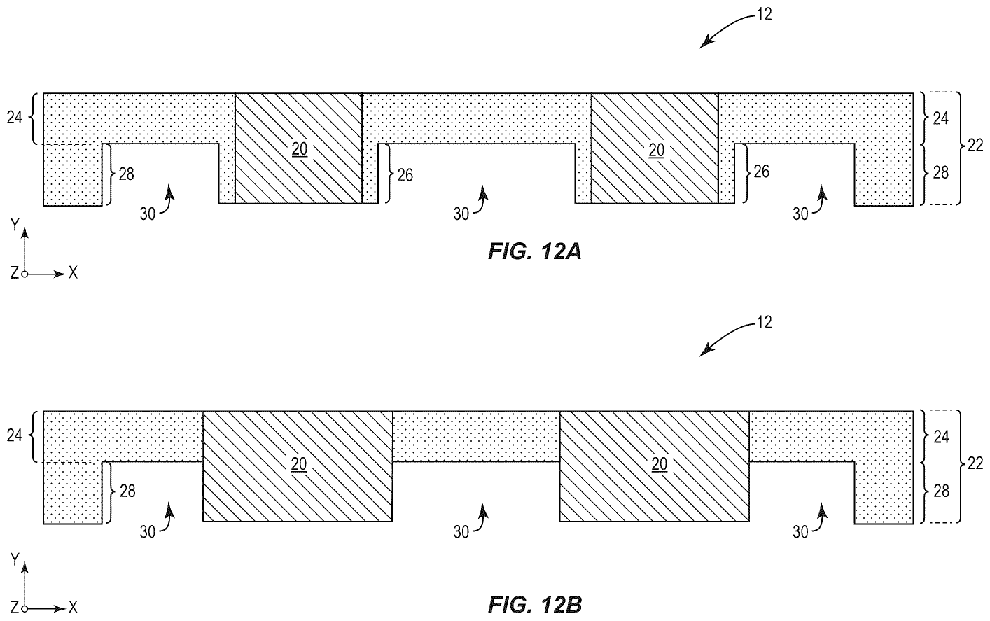

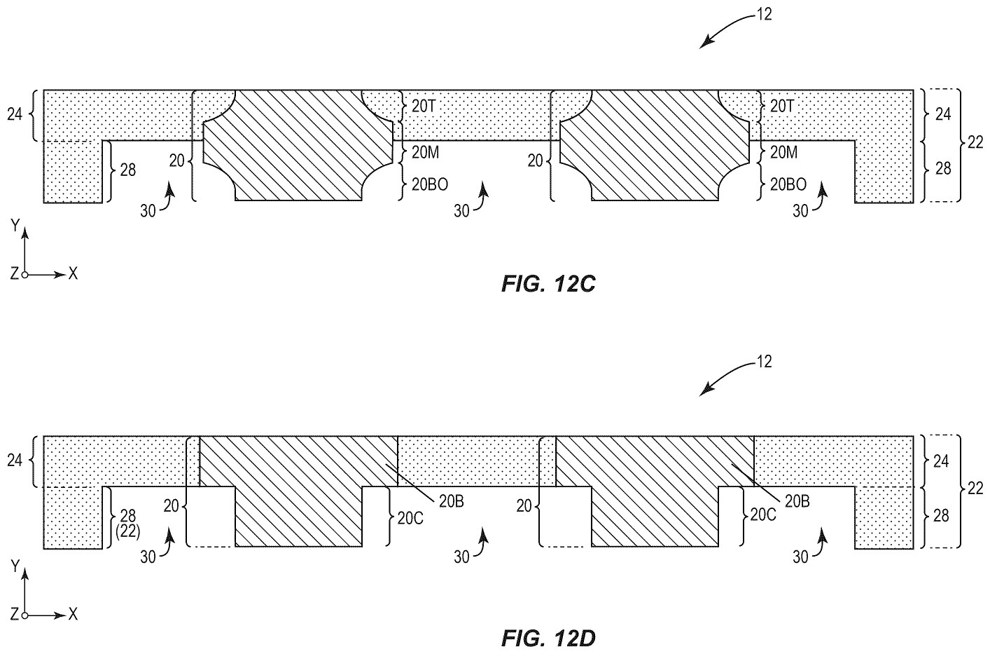

Next, the recess 30 is formed surrounding each heat spreader 20 to convert the patterned lid body 22PA to the lid body 22, and to provide the coined lid 12 (step 116), as illustrated in FIGS. 12A-12D. In this illustration, the recess 30 extends from a bottom surface of the lid body 22 toward a top surface of the lid body 22 without extending through. A remaining top portion of the lid body 22 (above the recess 30) is the lid base 24, and a remaining periphery portion of the lid body 22 (surrounding the recess 30) is the lid wall 28.

In some embodiments, none of the heat spreaders 20 is exposed to the recess 30. Interior portions of the lid body 22, which reside underneath the lid base 24 and surround corresponding heat spreaders 20, respectively, are the lid ridges 26, as illustrated in FIG. 12A (e.g., used to form the air-cavity package 10 shown in FIG. 1). Herein, the formation of the recess 30 is only related to removal of portions of the patterned lid body 22PA. In other words, the recess 30 is formed by partially removing the patterned lid body 22PA without touching any of the heat spreaders 20. As such, each heat spreader 20 extends through the lid base 24 and a corresponding lid ridge 26, and the recess 30 is defined underneath the lid base 24 and among the lid wall 28 and the lid ridges 26. In some embodiments, an upper portion of each heat spreader 20 extends through the lid base 24, while a lower portion of each heat spreader 20 is exposed to the recess 30, as illustrated in FIG. 12B (e.g., used to form the air-cavity package 10 shown in FIG. 3). The formation of the recess 30 is still only related to removal of portions of the patterned lid body 22PA. However, no portion of the lid body 24 is retained surrounding the lower portion of each heat spreader 20 (i.e., no lid ridge 26 is included in the lid body 24). As such, the recess 30 is defined underneath the lid base 24 and among the lid wall 28 and the heat spreaders 20.

In the cases that each via hole 54 has an octagonal shape, then each formed heat spreader 20 will also have an octagonal shape, as illustrated in FIG. 12C (e.g., used to form the air-cavity package 10 shown in FIG. 4). During the formation of the recess 30, some interior portions of the patterned lid body 22PA are removed, and portions of each heat spreader 20 are exposed to the recess 30. For the purpose of this illustration, each heat spreader 20 is divided into the top portion 20T, the middle portion 20M, and the bottom portion 20BO. A size of each top portion 20T and a size of each bottom portion 20BO are smaller than a size of a corresponding middle portion 20M. The top portion 20T of each heat spreader 20 extends through the lid base 24, where a top surface of the top portion 20T (i.e., the top surface of each heat spreader 20) is not covered by any portion of the lid body 22 (e.g., the top surface of each heat spreader 20 is flashed with a top surface of the lid base 24). The middle portion 20M and the bottom portion 20BO of each heat spreader 20 protrude from the bottom surface of the lid base 24 and are exposed to the recess 30. In different applications, the lid base 24 may cover more or less of each heat spreader 20. The recess 30 is defined underneath the lid base 24 and among the lid wall 28 and the heat spreaders 20.

In some embodiments, the formation of the recess 30 is not only related to the removal of portions of the patterned lid body 22PA, but is also related to the reshaping of each heat spreader 20 (step 116A). As illustrated in FIG. 12D (e.g., used to form the air-cavity package 10 shown in FIG. 2), the recess 30 is formed by partially removing the patterned lid body 22PA and partially removing each heat spreader 20. In particular, each heat spreader 20 may be modified from a rectangular shape to a T-shape in the x-y dimensions. Herein, each heat spreader 20 may include the unmodified spreader base 20B that extends through the lid base 24, and the modified/narrowed spreader column 20C that protrudes from the bottom surface of the spreader base 20B and is exposed to the recess 30. The recess 30 is defined underneath the lid base 24 and among the lid wall 28 and the spreader columns 20C.

Optionally, there might be another grinding step applied to a bottom surface of one or more certain heat spreaders 20 (step 118, not shown in a separate Figure), so as to planarize the bottom surface of the certain heat spreader(s) 20 and/or to provide a more appropriate height of the certain heat spreader(s) 20 for the corresponding flip-chip die(s) 18 in the following steps. As such, the lid wall 28 may extend vertically beyond bottom surfaces of the certain heat spreader(s) 20. In a case where the lid ridges 26 exists, one or more certain lid ridges 26 corresponding to the certain heat spreader(s) 20 may also be ground and may have a shorter height than the lid wall 28.

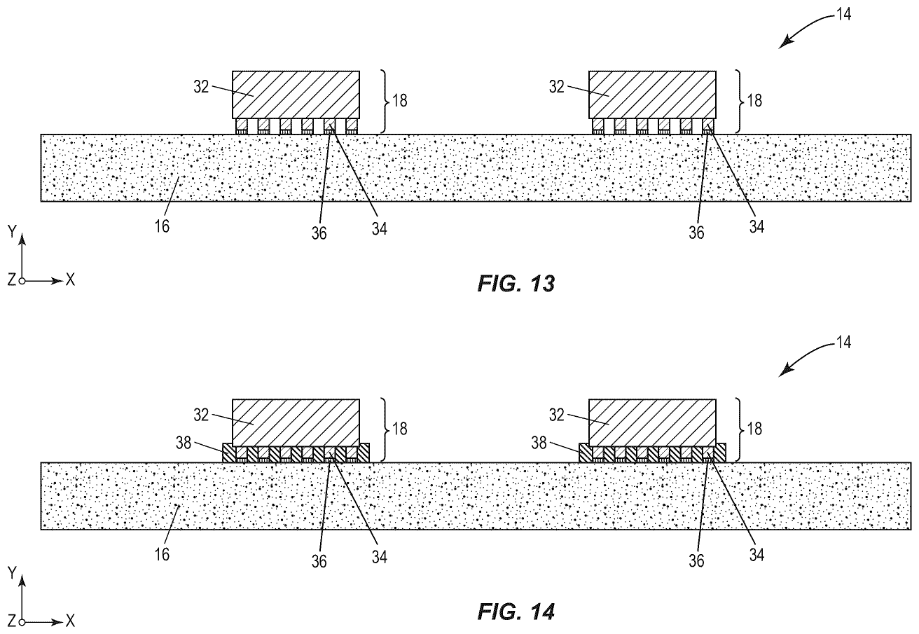

On the other hand, a formation of the base assembly 14 starts with attaching the flip-chip dies 18 to the top surface of the package substrate 16 (step 202), as illustrated in FIG. 13. For the purpose of this illustration, there are two flip-chip dies 18 attached to the top surface of the package substrate 16. Each flip-chip die 18 includes one die body 32 and the interconnects 34 extending outwardly from the bottom surface of the die body 32 and is coupled to the top surface of the package substrate 16 via solder caps 36. The die body 32 may be formed from GaN, and the interconnects 34 may be copper pillars. In different applications, there might be fewer or more flip-chip dies 18, and there might be other components, such as resistors, capacitors, inductors, wire-bonding dies, and/or other SMDs attached to the top surface of the package substrate 16. Next, each flip-chip die 18 is underfilled by the underfilling material 38 (step 204), as illustrated in FIG. 14. The underfilling material 38, which may be an epoxy material, encapsulates each interconnect 34 and fills gaps between the bottom surface of the die body 32 of each flip-chip die 18 and the top surface of the package substrate 16. A curing step may be followed to harden the underfilling material 38 (not shown).

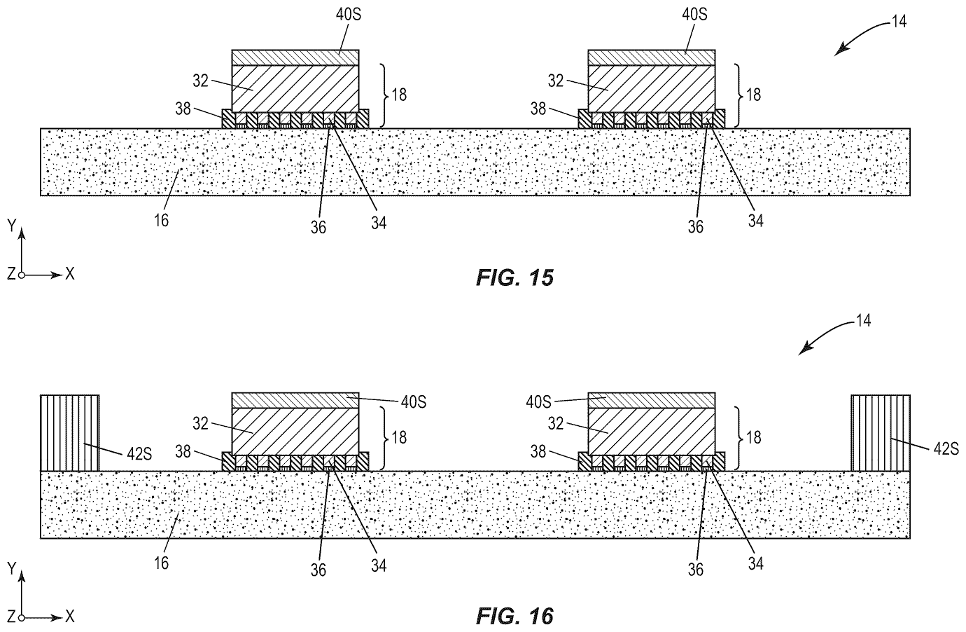

A sintering material 40S is then applied to the backside of each flip-chip die 18 (step 206), as illustrated in FIG. 15. Herein, the sintering material 40S may also be the engineered nano copper paste 20P, which is capable of being customized to tune the CTE so as to match the corresponding flip-chip dies 18. In some cases, the sintering material 40S may be sintering silver. The sintering material 40S may be applied by a dispensing process. The applied amount of the sintering material 40S is determined by the height of each flip-chip die 18 and a curing shrinkage rate of the sintering material 40S. For a non-limited example, if one flip-chip die 18 is relatively short, the amount of the sintering material 40S applied to such flip-chip die 18 needs to be relatively large, so as to ensure a reliable connection between the flip-chip die 18 and the corresponding heat spreader 20 in the following step. In addition, if the curing shrinkage rate of the sintering material 40S is relatively large, the amount of the sintering material 40S applied to such flip-chip die 18 needs to be relatively large, so as to remain the reliable connection between the flip-chip die 18 and the corresponding heat spreader 20 after a curing step.

Once the base assembly 14 is formed, a lid sealing material 42S may be applied on the top surface of the package substrate 16 (step 208), as illustrated in FIG. 16. Herein, the position of the lid sealing material 42S on the top surface of the package substrate 16 corresponds to the position/shape of the lid wall 28 on the lid base 24 (in the x-z dimensions). The lid sealing material 42S may be an epoxy material and applied by a dispense process. An applied amount of the lid sealing material 42S is determined by a curing shrinkage rate of the lid sealing material 42S. For a non-limited example, if the curing shrinkage rate of the lid sealing material 42S is relatively large, the amount of the lid sealing material 42S applied on the top surface of the package substrate 16 needs to be relatively large, so as to ensure reliable sealing between the coined lid 12 and the base assembly 14 after a curing step, and to provide the sealed air cavity 46.

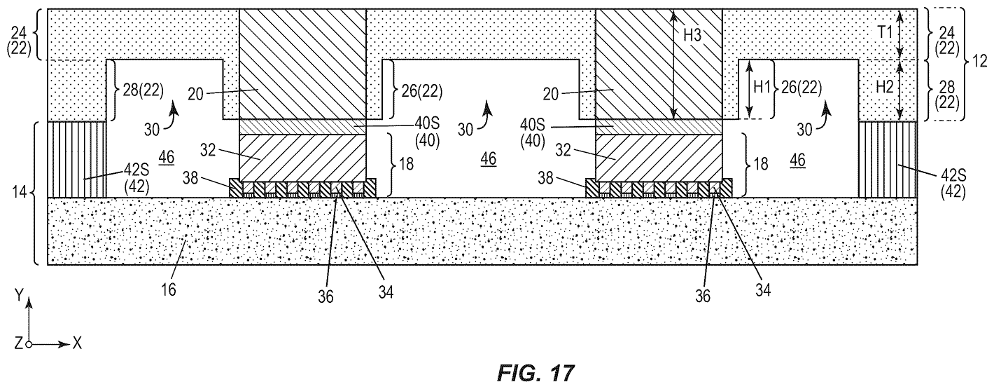

Since the coined lid 12 and the base assembly 14 are formed separately, the coined lid 12 and the base assembly 14 can be formed simultaneously. After the coined lid 12 and the base assembly 14 are completed, the coined lid 12 is placed over the base assembly 14 (step 302), as illustrated in FIG. 17. Herein, each heat spreader 20 within the coined lid 12 is aligned with the corresponding flip-chip die 18, and the sintering material 40S is coupled between each heat spreader 20 and the corresponding flip-chip die 18. The lid sealing material 42S is coupled between the lid wall 28 and the top surface of the package substrate 16.

Following the placement of the coined lid 12, the sintering material 40S and the lid sealing material 42S are cured simultaneously at a low temperature of approximately 150-170° C. (step 304, not shown in a separate Figure). Subsequently, an additional curing step (step 304A) may be performed at a temperature of approximately 175° C. and 200° C. to enhance the sintering density of the sintering material 40S. After the one or two curing steps, the sintering material 40S is converted to the sintered components 40, while the lid sealing material 42S is converted to the lid sealed component 42. Since the applied amount of the sintering material 40S and the applied amount of the lid sealing material 42S are carefully determined based on their curing shrinkage rates in view with the thicknesses of the flip-chip dies 18, each sintered component 40 provides a reliable connection between one flip-chip die 18 and its corresponding heat spreader 20, while the lid sealed component 42 provides reliable sealing between the coined lid 12 and the package substrate 16. In addition, since both the heat spreaders 20 and sintered components 40 may be formed from the tunable engineered nano copper paste 20P (which can leverage the CTE in the range of 5-16 ppm), each combination of one sintered component 40 and its corresponding heat spreader 20 helps to mitigate the CTE mismatches between the lid body 22, the flip-chip dies 18, and the package substrate 16.

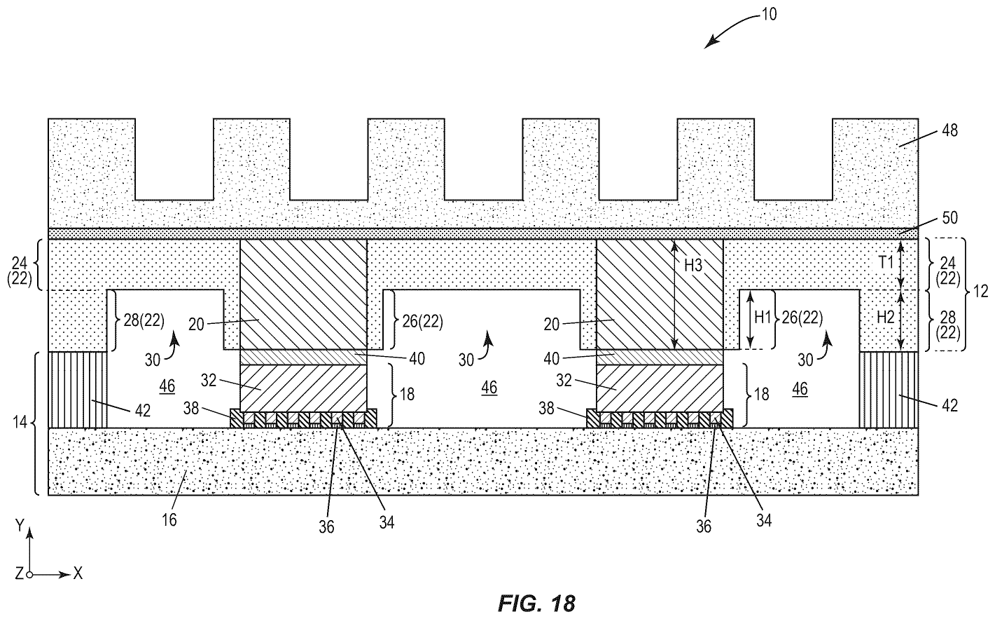

Finally, the heat sink 48 may be attached to the top surface of the coined lid 12 via the adhesion layer 50 (step 306), as illustrated in FIG. 18. As such, the heat generated from the flip-chip dies 18 can be dissipated through the combination of the sintered components 40 and the heat spreaders 20, and towards the heat sink 48.

The systems and methods for top side cooling of an air-cavity package, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

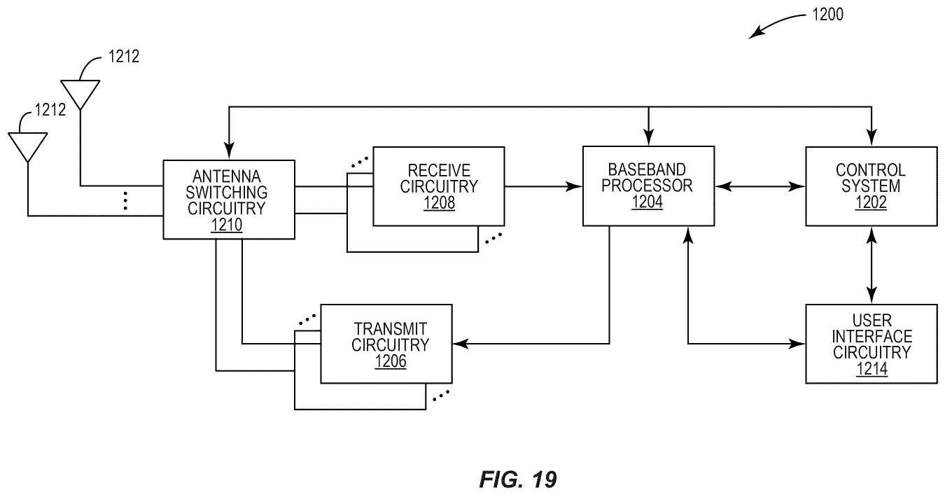

With reference to FIG. 19, the concepts described above may be implemented in various types of communication devices 1200, such as those listed in the previous paragraph. The communication devices 1200 will generally include a control system 1202, a baseband processor 1204, transmit circuitry 1206, receive circuitry 1208, antenna switching circuitry 1210, multiple antennas 1212, and user interface circuitry 1214. Herein, at least one or any combination of the control system 1202, the baseband processor 1204, the transmit circuitry 1206, and the receive circuitry 1208 may be implemented in the air-cavity package 10 (e.g. implemented in the one or more flip-chip dies 18) described above.

In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives radio frequency signals via the antennas 1212 and through the antenna switching circuitry 1210 from one or more base stations. A low noise amplifier and a filter of the receive circuitry 1208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1212 through the antenna switching circuitry 1210 to the antennas 1212. The multiple antennas 1212 and the replicated transmit and receive circuitries 1206, 1208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An air-cavity package comprising:
a base assembly that includes a package substrate and at least one flip-chip die attached to a top surface of the package substrate;
a coined lid placed over the base assembly and including a lid body and at least one heat spreader, wherein:
the lid body includes a lid base and a lid wall protruding from a periphery of a bottom surface of the lid base towards the top surface of the package substrate;
the at least one heat spreader extends through the lid base and protrudes from the bottom surface of the lid base;
a recess is defined underneath the lid base, surrounding the at least one heat spreader, and surrounded by the lid wall; and
the at least one heat spreader is positioned over, aligned with, and thermally coupled to the at least one flip-chip die; and
a lid sealing component that seals the lid wall to the top surface of the package substrate, wherein the recess within the coined lid and a gap surrounding the at least one flip-chip die combine to form an air cavity, which is sealed by a combination of the coined lid, the package substrate, and the lid sealed component, and the at least one flip-chip die is encapsulated within the air cavity.

2. The air-cavity package of claim 1, wherein the at least one heat spreader is formed from an engineered nano copper paste, which is capable of being customized in a coefficient of thermal expansion (CTE), in a range of 5-16 ppm.

3. The air-cavity package of claim 1, wherein the at least one flip-chip die includes a die body and a plurality of interconnects extending outwardly from a bottom surface of the die body and is coupled to the top surface of the package substrate.

4. The air-cavity package of claim 3, wherein the die body is formed from gallium nitride (GaN).

5. The air-cavity package of claim 3, wherein the at least one heat spreader is thermally coupled to a backside of the die body via a sintered component.

6. The air-cavity package of claim 5, wherein both the at least one heat spreader and the sintered component are formed from an engineered nano copper paste, which is capable of being customized in the CTE, in a range of 5-16 ppm.

7. The air-cavity package of claim 1, wherein the at least one heat spreader has a shape like one of a group consisting of rectangular, square, round, T-shaped, and octagonal.

8. The air-cavity package of claim 1, wherein:
the lid body further includes at least one lid ridge, which is located in an inner area of the lid body and protrudes from the bottom surface of the lid base towards the top surface of the package substrate; and
the at least one heat spreader extends through the lid base and the at least one lid ridge, such that a top surface and a bottom surface of the at least one heat spreader are not covered by any portion of the lid body, while side surfaces of the at least one heat spreader are covered by the lid body.

9. The air-cavity package of claim 1, wherein a portion of the at least one heat spreader is not covered by the lid body and is exposed to the recess.

10. The air-cavity package of claim 1, wherein the lid body is formed from a flame-retardant glass reinforced epoxy laminate material (FR4) or liquid crystal polymer (LCP).

11. The air-cavity package of claim 1 further comprising a heat sink, which is coupled to a top surface of the coined lid via an adhesion layer.

12. The air-cavity package of claim 1 wherein the lid sealing component is formed from an epoxy material.

13. A method of fabricating an air-cavity package comprising:
forming a base assembly that includes a package substrate and at least one flip-chip die attached to a top surface of the package substrate;
forming a coined lid that includes a lid body and at least one heat spreader, wherein:
the lid body includes a lid base and a lid wall protruding from a periphery of a bottom surface of the lid base towards the top surface of the package substrate;
the at least one heat spreader extends through the lid base and protrudes from the bottom surface of the lid base; and
a recess is defined underneath the lid base, surrounding the at least one heat spreader, and surrounded by the lid wall;
placing the coined lid over the base assembly, such that the at least one heat spreader is positioned over, aligned with, and thermally coupled to the at least one flip-chip die; and
sealing the lid wall of the coined lid to the top surface of the package substrate by a lid sealing component, wherein the recess within the coined lid and a gap surrounding the at least one flip-chip die combine to form an air cavity, which is sealed by a combination of the coined lid, the package substrate, and the lid sealed component, and the at least one flip-chip die is encapsulated within the air cavity.

14. The method of claim 13 wherein the at least one heat spreader is formed from an engineered nano copper paste, which is capable of being customized in CTE, in a range of 5-16 ppm.

15. The method of claim 14 further comprising applying a sintering material to a backside of the at least one flip-chip die after the base assembly is formed, such that when the coined lid is placed over the base assembly, the at least one heat spreader is coupled to the at least one flip-chip die via the sintering material.

16. The method of claim 15 wherein the sintering material is the engineered nano copper paste.

17. The method of claim 16 further comprising applying a lid sealing material on a top surface of the package substrate after the base assembly is formed, wherein:
a position of the lid sealing material on the top surface of the package substrate corresponds to a position of the lid wall on the lid base, such that when the coined lid is placed over the base assembly, the lid sealing material is coupled between the top surface of the package substrate and the bottom surface of the lid wall.

18. The method of claim 17 wherein the lid sealing material is an epoxy material.

19. The method of claim 18 wherein sealing the lid wall of the coined lid to the top surface of the package substrate includes at least one curing processes, which converts the lid sealing material to the lid sealing component connecting the bottom surface of the lid wall to the top surface of the package substrate, and convert the sintering material to a sintered component connecting a bottom surface of the at least one heat spreader to the backside of the at least one flip-chip die.

20. A communication device comprising:
a control system;
a baseband processor;
receive circuitry; and
transmit circuitry, wherein at least one or any combination of the control system, the baseband processer, the transmit circuitry, and the receive circuitry is implemented in an air-cavity package, which has a base assembly, a coined lid, and a lid sealing component, wherein:
the base assembly includes a package substrate and at least one flip-chip die attached to a top surface of the package substrate;
the coined lid is placed over the base assembly and includes a lid body and at least one heat spreader;
the lid body includes a lid base and a lid wall protruding from a periphery of a bottom surface of the lid base towards the top surface of the package substrate;
the at least one heat spreader extends through the lid base and protrudes from the bottom surface of the lid base;
a recess is defined underneath the lid base, surrounding the at least one heat spreader, and surrounded by the lid wall;
the at least one heat spreader is positioned over, aligned with, and thermally coupled to the at least one flip-chip die; and
the lid sealing component seals the lid wall to the top surface of the package substrate, wherein the recess within the coined lid and a gap surrounding the at least one flip-chip die combine to form an air cavity, which is sealed by a combination of the coined lid, the package substrate, and the lid sealed component, and the at least one flip-chip die is encapsulated within the air cavity.
